(19) United States
(12) Patent Application Publication
(10) Pub. No.: US 2005/0030206 A1
(43) Pub. Date: Feb. 10, 2005

(54) High-resolution timers and pulse width modulators

(76) Inventor: Qiong M. Li, Cortlandt Manor, NY (US)

Correspondence Address: PHILIPS INTELLECTUAL PROPERTY & STANDARDS, P.O. BOX 3001, BRIARCLIFF MANOR, NY, 10510, US

(21) Appl. No.: 10/912,454

(22) Filed: Aug. 5, 2004

Related U.S. Application Data
(60) Provisional application No. 60/493,838, filed on Aug. 8, 2003.

(51) Int. Cl. H03M 5/08

(52) U.S. Cl. 341/53

(57) ABSTRACT

A method of operating a timer (30, 110) involves a generation of a first clock signal indicative of a time shifting of a second clock signal, a generation of a first timing signal having a first pulse, and a generation of a second timing signal having a second pulse indicative of a mixture of the first clock signal and the first pulse of the first timing signal. A method of operating a PWM (70, 150, 190) involves a generation of a first clock signal indicative of a time shifting of a second clock signal, a generation of a first pulse width modulated signal having a first pulse width, and a generation of a second pulse width modulated signal having a second pulse width indicative of a mixture of the first clock signal and the first pulse width of the first pulse width modulated signal.

The present invention generally relates to timers and pulse width modulators. The present invention specifically relates to a family of timers and pulse width modulators operating within a desirable clock frequency range with an optional asynchronous restart capability.

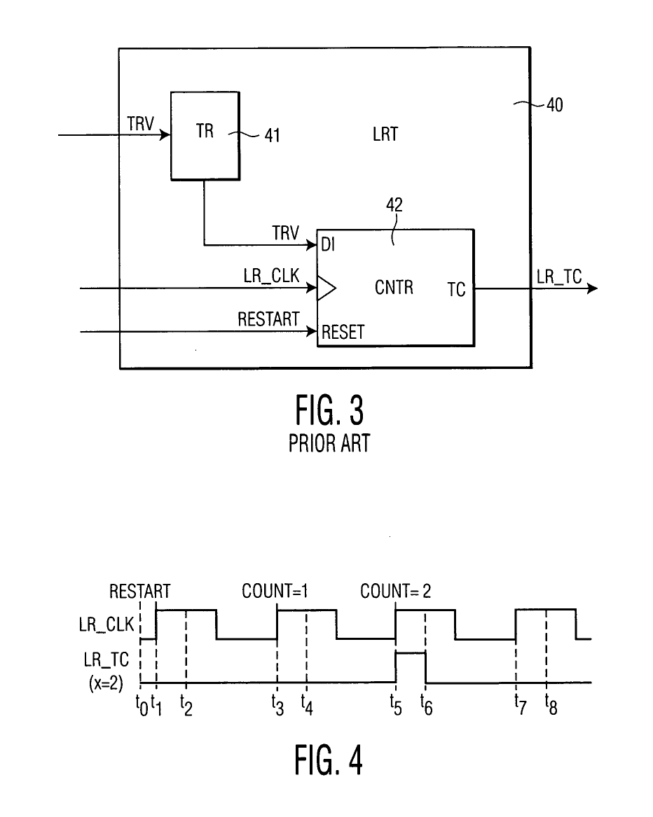

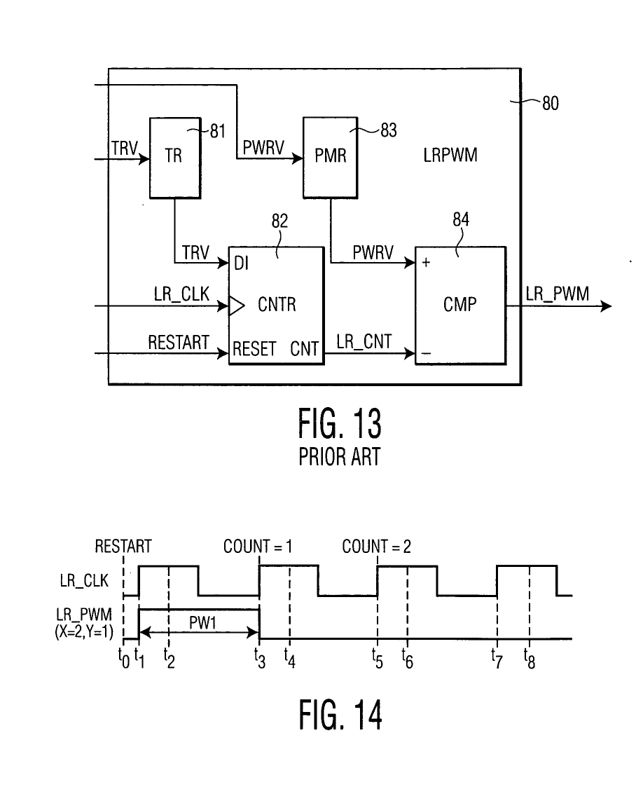

A time resolution of known timers (e.g., timer 40 illustrated in FIG. 3) and known pulse width modulators (“PWMs”) (e.g., PWM 80 illustrated in FIG. 13) is proportional to the frequency of the incoming clock signal (e.g., clock signal LR_CLK illustrated in FIGS. 3 and 13). A drawback to known timers and known PWMs is an increase in power consumption, noise and cost when implementing a high time resolution (e.g., 1 ns) with a very high frequency of the incoming clock signal (e.g., 1 GHz).

The present invention provides timers and PWMs that can be operated at a low clock frequency of a system clock signal (e.g., 50 MHz-100 MHz) with a high time resolution (e.g., 1 ns) and an optional implementation of an asynchronous restart capability.

One form of the present invention is method of operating a timer involving a generation of a first clock signal indicative of a time shifting of a second clock signal, a generation of a first timing signal having a first pulse, and a generation of a second timing signal having a second pulse indicative of a mixture of the first clock signal and the first pulse of the first timing signal. A time differential between the first pulse of the first timing signal and the second pulse of the second timing signal is a function of a time resolution of the timer.

The term “mixture” is defined herein as a generation of an output signal (e.g., the second timing signal) having one or more signal characteristics of each input signal (e.g., the first clock signal and the first timing signal).

A second form of the present invention is a timer comprising a time shifter module, a timer module and a timer mixer module. The time shifter module generates a first clock signal indicative of a time shifting of a second clock signal. The timer module generates a first timing signal having a first pulse. The timer mixer module is in electrical communication with the time shifter module and the timer module to receive the first clock signal and the first timing signal, respectively. The timer mixer module generates a second timing signal having a second pulse indicative of a mixture of the first clock signal and the first pulse of the first timing signal. A time differential between the first pulse of the first timing signal and the second pulse of the second timing signal is a function of a time resolution of the timer.

The term “electrical communication” is defined herein as an electrical connection, electrical coupling or any other technique for electrically applying an output of one device (e.g., the time shifter module) to an input of another device (e.g., the timer mixer).

A third form of the present invention is a method of operating a pulse width modulator involving a generation of a first clock signal indicative of a time shifting of a second clock signal, a generation of a first pulse width modulated signal having a first pulse width, and a generation of a second pulse width modulated signal having a second pulse width indicative of a mixture of the first clock signal and the first pulse width of the first pulse width modulated signal. A width differential between the first pulse width of the first pulse width modulated signal and the second pulse width of the second pulse width modulated signal is a function of a time resolution of the pulse width modulator.

A fourth form of the present invention is a pulse width modulator comprising a time shifter module, a PWM module and a PWM mixer module. The time shifter module generates a first clock signal indicative of a time shifting of a second clock signal. The PWM module generates a first pulse width modulated signal having a first pulse width. The PWM mixer module is in electrical communication with the time shifter module and the PWM module to receive the first clock signal and the first pulse width modulated signal, respectively. The PWM mixer module generates a second pulse width modulated signal having a second pulse width indicative of a mixture of the first clock signal and the first pulse width of the first pulse width modulated signal. A width differential between the first pulse width of the first pulse width modulated signal and the second pulse width of the second pulse width modulated signal is a function of a time resolution of the pulse width modulator.

The foregoing forms as well as other forms, features and advantages of the present invention will become further apparent from the following detailed description of the presently preferred embodiments, read in conjunction with the accompanying drawings. The detailed description and drawings are merely illustrative of the present invention rather than limiting, the scope of the present invention being defined by the appended claims and equivalents thereof.

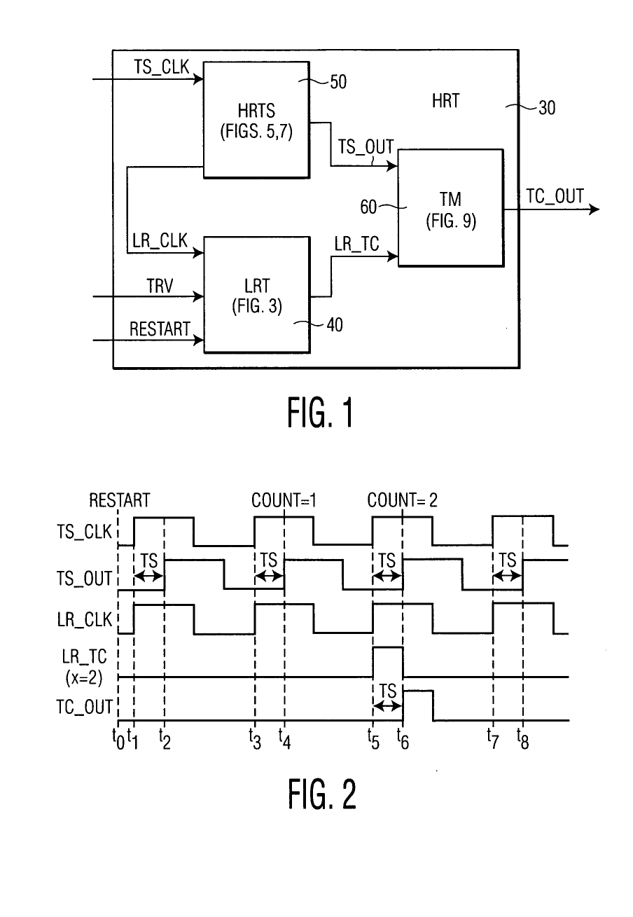

FIG. 1 illustrates a block diagram of a high-resolution timer in accordance with a first embodiment of the present invention;

FIG. 2 illustrates exemplary waveforms of various signals utilized and generated by the high-resolution timer illustrated in FIG. 1;

FIG. 3 illustrates a block diagram of a low-resolution timer as known in the art;

FIG. 4 illustrates exemplary waveforms of various signals utilized and generated by the low-resolution timer illustrated in FIG. 3;

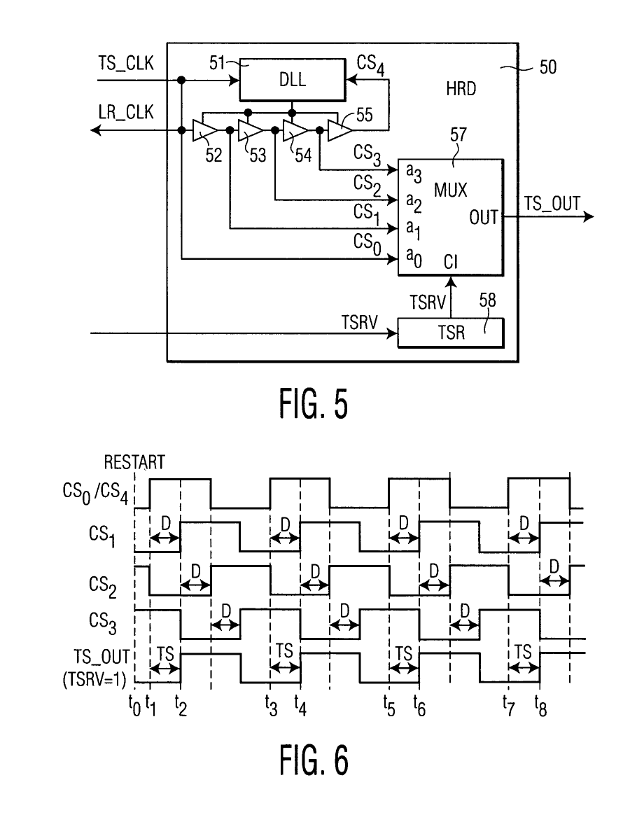

FIG. 5 illustrates a block diagram of a high-resolution time shifter in accordance with a second embodiment of the present invention;

FIG. 6 illustrates exemplary waveforms of various signals utilized and generated by the high-resolution time shifter illustrated in FIG. 5;

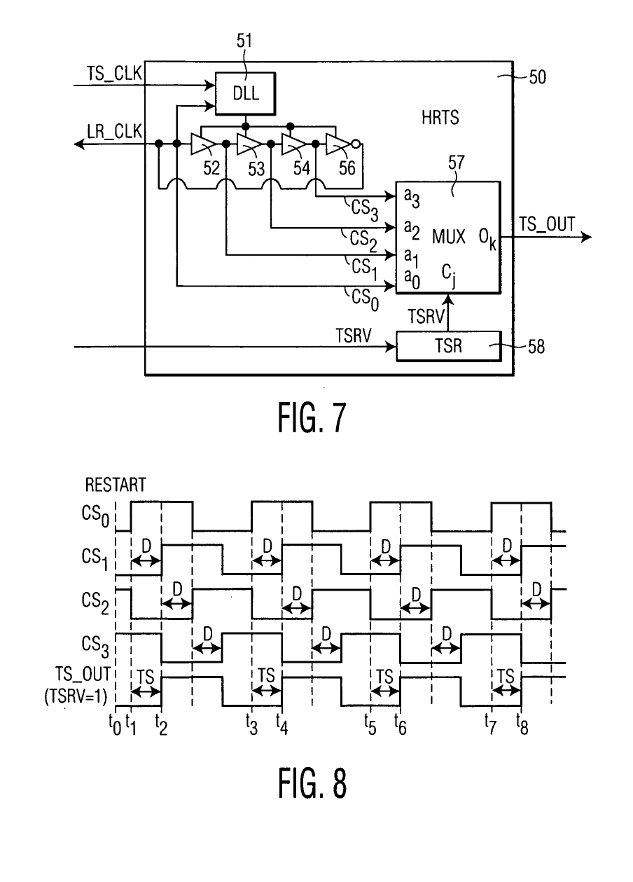

FIG. 7 illustrates a block diagram of a high-resolution time shifter in accordance with a third embodiment of the present invention;

FIG. 8 illustrates exemplary waveforms of various signals utilized and generated by the high-resolution time shifter illustrated in FIG. 7;

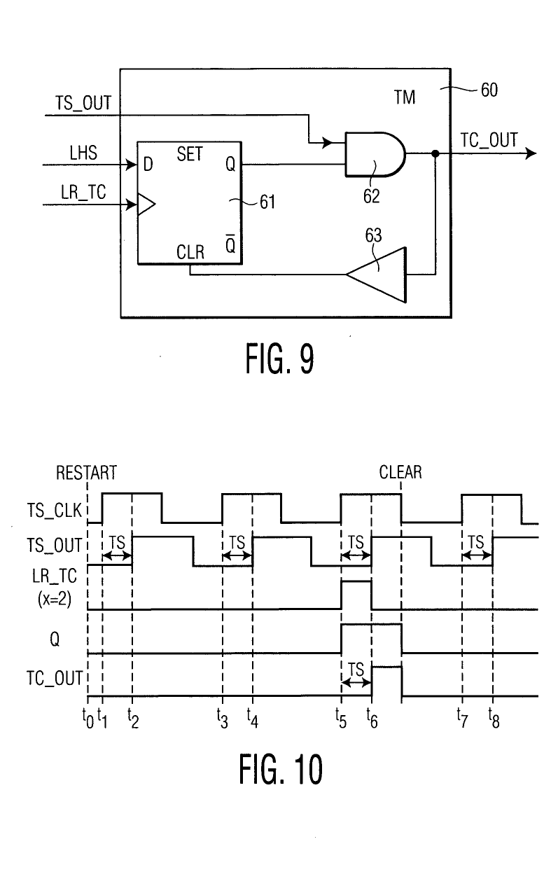

FIG. 9 illustrates a block diagram of a timer mixer in accordance with a fourth embodiment of the present invention;

FIG. 10 illustrates exemplary waveforms of various signals utilized and generated by the timer mixer illustrated in FIG. 9;

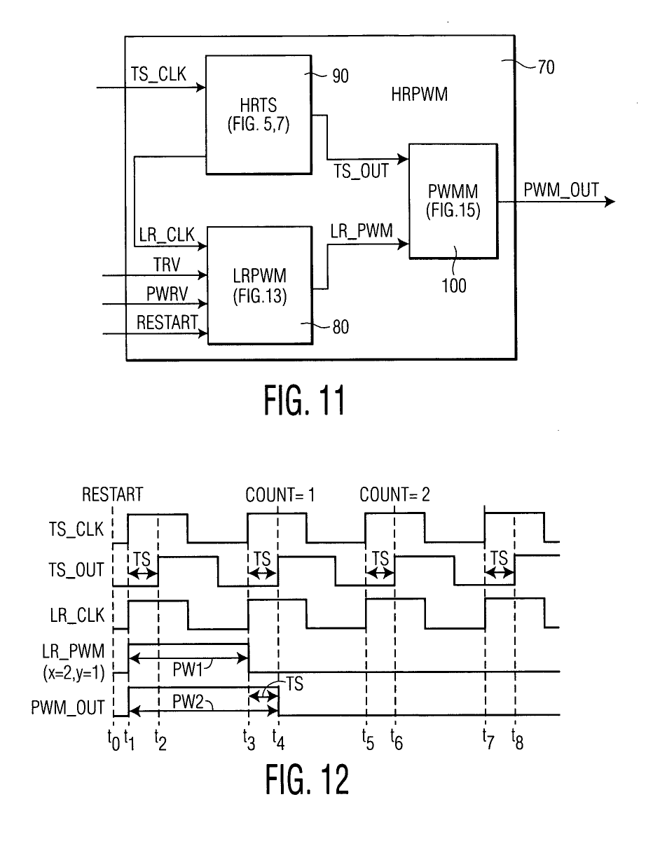

FIG. 11 illustrates a block diagram of a high-resolution pulse width modulator in accordance with a fifth embodiment of the present invention;

FIG. 12 illustrates exemplary waveforms of various signals utilized and generated by the high-resolution pulse width modulator illustrated in FIG. 11;

FIG. 13 illustrates a block diagram of a low-resolution pulse width modulator as known in the art;

FIG. 14 illustrates exemplary waveforms of various signals utilized and generated by the low-resolution pulse width modulator illustrated in FIG. 13;

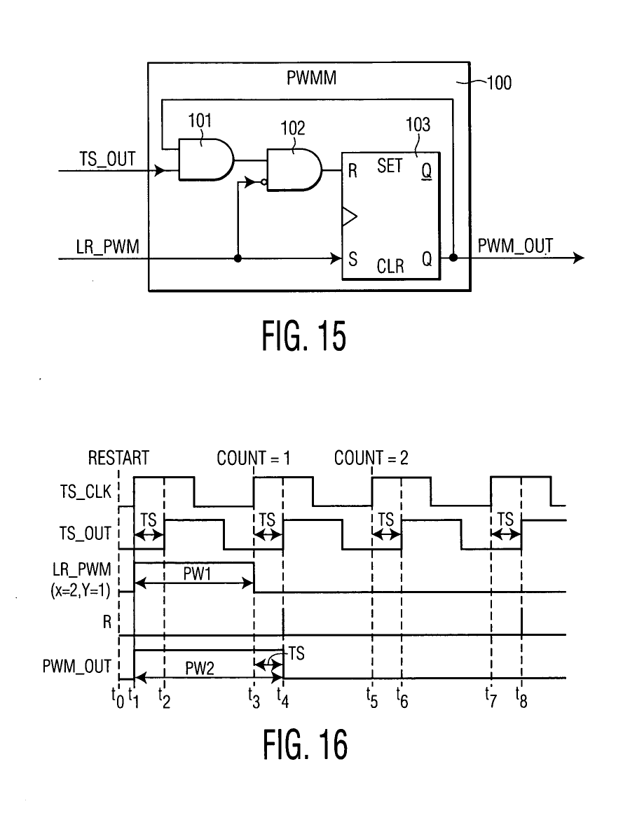

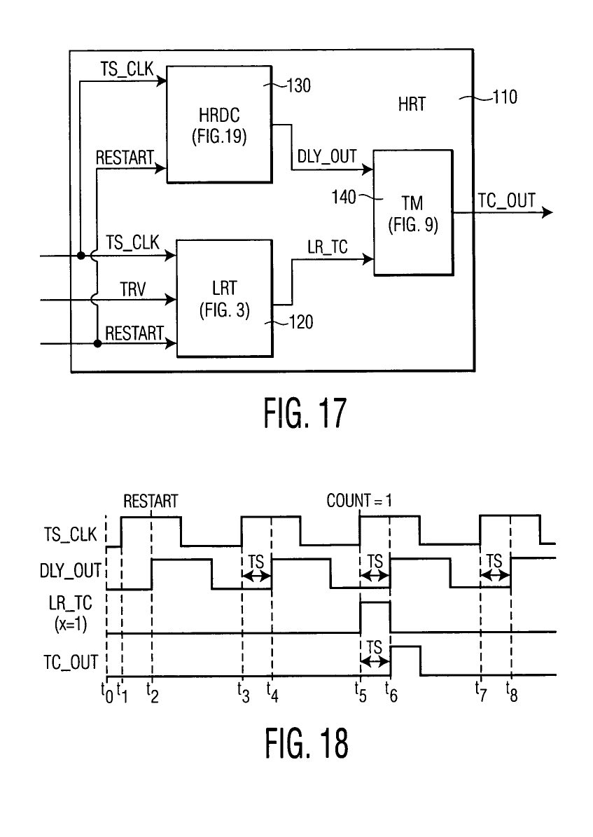

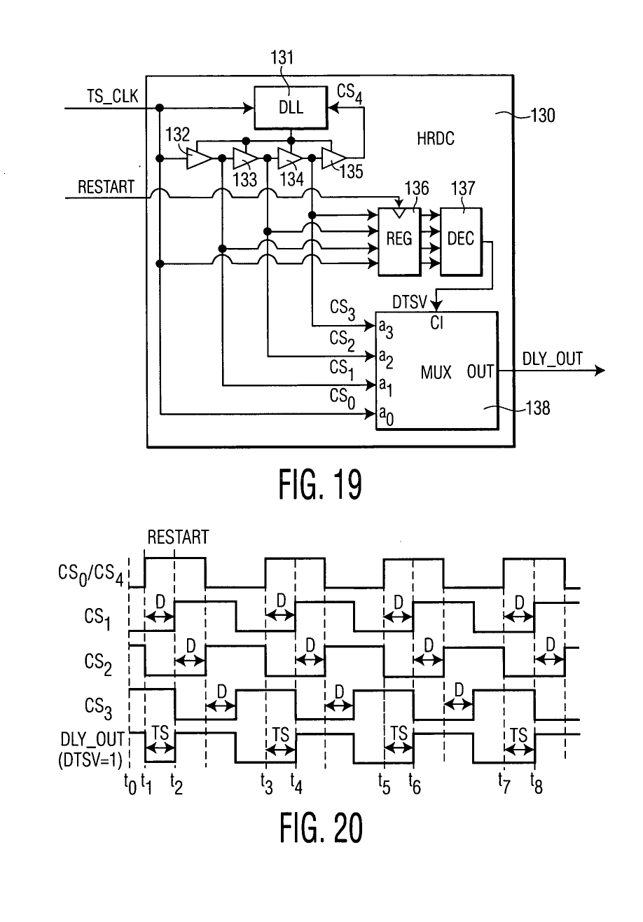

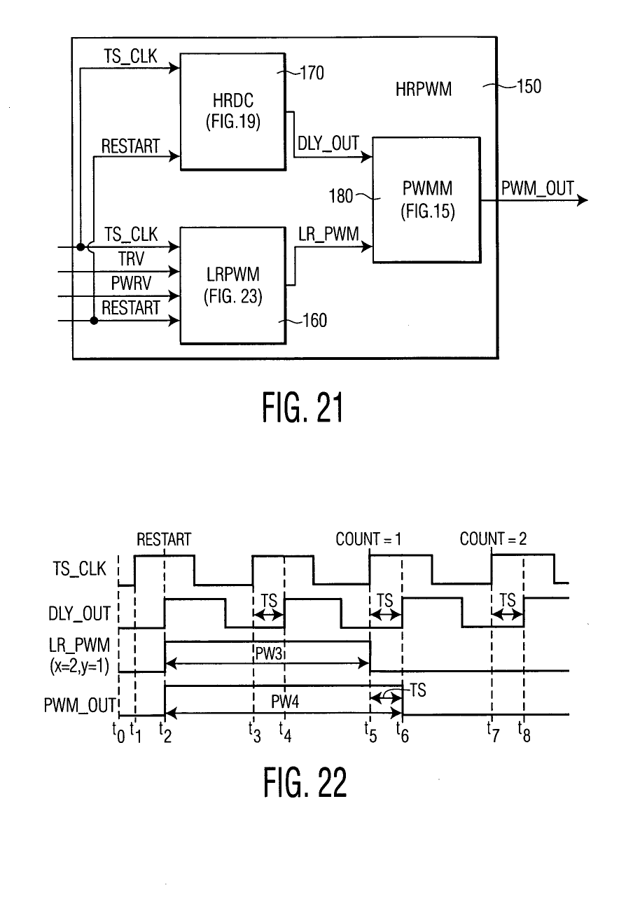

FIG. 15 illustrates a block diagram of a pulse width modulator mixer in accordance with a sixth embodiment of the present invention;

FIG. 16 illustrates exemplary waveforms of various signals utilized and generated by the pulse width modulator mixer illustrated in FIG. 15;

FIG. 17 illustrates a block diagram of a high-resolution timer in accordance with a seventh embodiment of the present invention;

FIG. 18 illustrates exemplary waveforms of various signals utilized and generated by the high-resolution timer illustrated in FIG. 17;

FIG. 19 illustrates a block diagram of a high-resolution delay compensator in accordance with an eighth embodiment of the present invention;

FIG. 20 illustrates exemplary waveforms of various signals utilized and generated by the high-resolution delay compensator illustrated in FIG. 19;

FIG. 21 illustrates a block diagram of a high-resolution pulse width modulator in accordance with a ninth embodiment of the present invention;

FIG. 22 illustrates exemplary waveforms of various signals utilized and generated by the high-resolution pulse width modulator illustrated in FIG. 21;

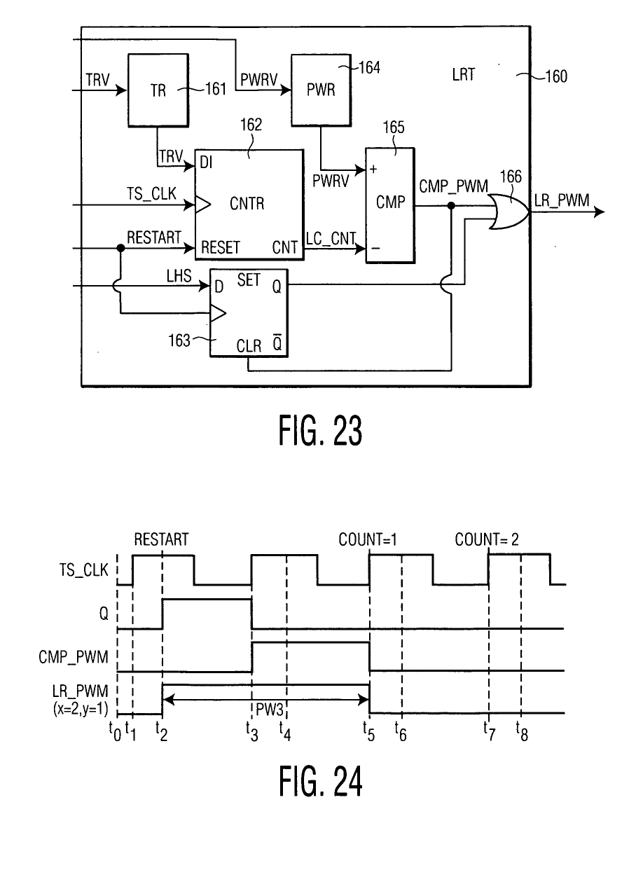

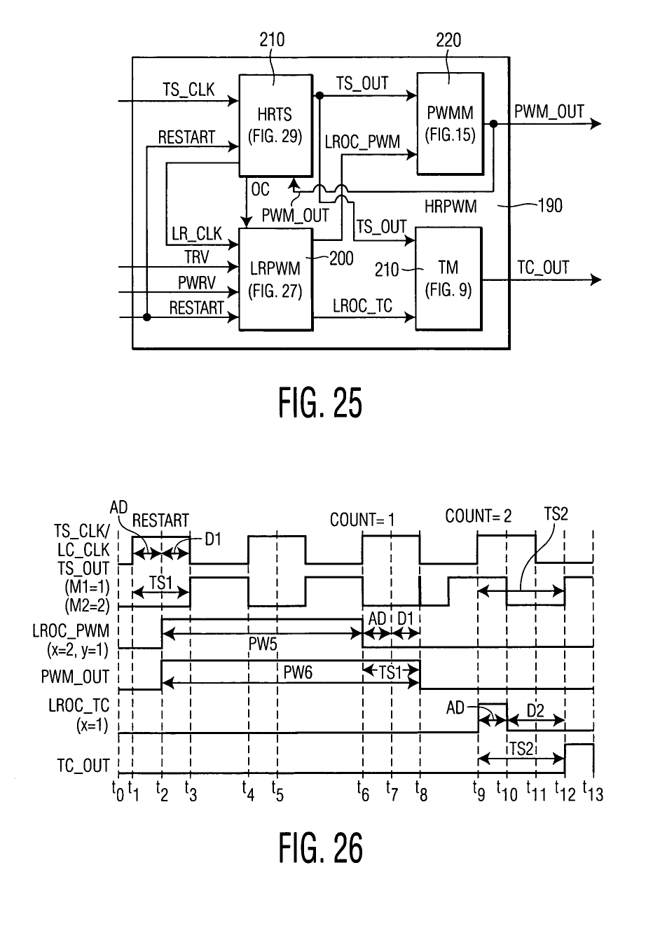

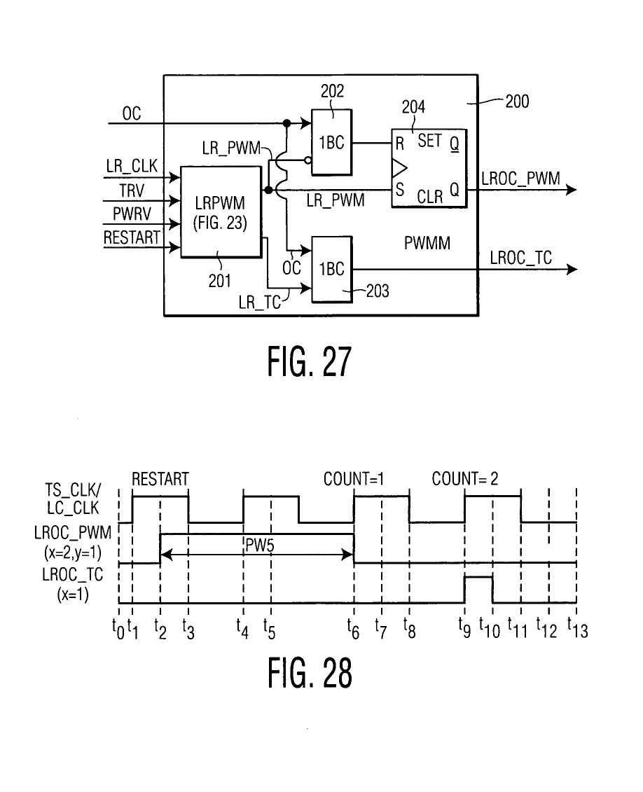

FIG. 23 illustrates a block diagram of a low-resolution pulse width modulator in accordance with a tenth embodiment of the present invention;

FIG. 24 illustrates exemplary waveforms of various signals utilized and generated by the low-resolution pulse width modulator illustrated in FIG. 23;

FIG. 25 illustrates a block diagram of a high-resolution pulse width modulator in accordance with an eleventh embodiment of the present invention;

FIG. 26 illustrates exemplary waveforms of various signals utilized and generated by the high-resolution pulse width modulator illustrated in FIG. 25;

FIG. 27 illustrates a block diagram of a low-resolution pulse width modulator in accordance with a twelfth embodiment of the present invention;

FIG. 28 illustrates exemplary waveforms of various signals utilized and generated by the low-resolution pulse width modulator illustrated in FIG. 27;

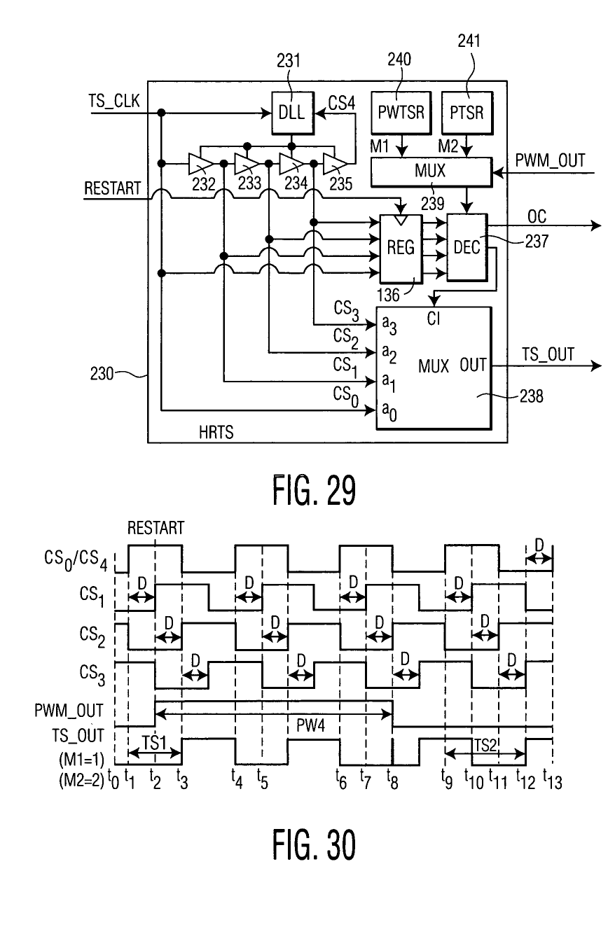

FIG. 29 illustrates a block diagram of a high-resolution delay compensator in accordance with a thirteenth embodiment of the present invention; and

FIG. 30 illustrates exemplary waveforms of various signals utilized and generated by the high-resolution delay compensator illustrated in FIG. 29.

A high-resolution timer (“HRT”) 30 as illustrated in FIG. 1 generates a high-resolution timing signal TC_OUT with a high time resolution (e.g., 1 ns) based on a low clock frequency of a system clock signal TS_CLK (e.g., a frequency between 50 MHz-100 MHz). To this end, high-resolution timer 30 employs a low-resolution timer (“LRT”) 40, a high-resolution time shifter (“HRTS”) 50, and a timer mixer (“TM”) 60.

Timer 40 is an electronic module structurally configured to generate a low-resolution timing signal LR_TC having a pulse indicative of a counting of x number of clock cycles of a low-resolution clock signal LR_CLK, where x≧2. Time shifter 50 is an electronic module structurally configured to generate a high-resolution clock signal TS_OUT indicative of a high-resolution time shifting of system clock signal TS_CLK. Time shifter 50 is also structurally configured to generate clock signal LR_CLK as a function of system clock signal TS_CLK. Mixer 60 is an electronic module structurally configured to generate timing signal TC_OUT having a pulse indicative of a mixture of clock signal TS_OUT and the pulse of timing signal LR_TC.

An exemplary operation of timer 30 will now be explained with reference to FIG. 2. In the exemplary operation, time shifter 50 receives system clock signal TS_CLK as illustrated in FIG. 2 and in response thereto, generates clock signals TS_OUT and LR_CLK as illustrated in FIG. 2. Clock signal TS_OUT represents a high-resolution time shift TS of system clock signal TS_CLK. Clock signals TS_CLK and LR_CLK are identical in the illustrated example of FIG. 2 to facilitate an understanding of the operation of timer 30. However, in practice, clock signals TS_CLK and LR_CLK may be dissimilar (e.g., clock signal LR_CLK can also represent the time shift TS of system clock signal TS_CLK).

A time register value TRV equaling two is communicated to timer 40 before a time t₀. Timer 40 is conventionally triggered by a restart signal RESTART at time t₀ to initiate a count of two (2) clock cycles of clock signal LR_CLK at a time t₁. Timer 40 generates a pulse of timing signal LR_TC upon counting two (2) clock cycles of clock signal LR_CLK at a time t₅ as illustrated in FIG. 2. Mixer 60 mixes clock signal TS_OUT and timing signal LR_TC to generate a pulse of timing signal TC_OUT at time t₆. The pulse of timing signal TC_OUT represents a time shift TS of the pulse of timing signal LR_TC based on clock signal TS_OUT, which represents a time shift TS of system clock signal TS_CLK. Time shift TS is a time differential between the pulse of timing signal LR_TC and the pulse of TC_OUT that is a function of the time resolution of timer 30.

In practice, structural configurations of timer 40, time shifter 50 and mixer 60 are dependent upon the commercial implementations of timer 30, and are therefore without limit.

FIG. 3 illustrates one embodiment of timer 40 (FIG. 1), which employs a time register (“TR”) 41 and a counter (“CNTR”) 42. Time register 41 is a conventional register for receiving, storing and communicating a time register value TRV as an indication of a total count threshold x for counter 42. Counter 42 is a conventional counter for generating timing signal LR_TC having a pulse indicative of a counting of x number of clock cycles of clock signal LR_CLK based on the time register value TRV.

An exemplary operation of timer 40 will now be explained with reference to FIG. 4. In the exemplary operation, time register 41 is electrically connected to a data input DI of counter 42 to electrically communicate a time register value TRV of 2 to counter 42 before time t₀ as illustrated in FIG. 4. Counter 42 is conventionally triggered by restart signal RESTART at time t₀ as illustrated in FIG. 4. Accordingly, counter 42 initiates a count of two (2) clock cycles of clock signal LR_CLK at a time t₁, as illustrated in FIG. 4, and generates a pulse of timing signal LR_TC upon counting two (2) clock cycles of clock signal LR_CLK at a time t₅ as illustrated in FIG. 4.

In practice, structural configurations of timer register 41 and counter 42 are dependent upon the commercial implementations of timer 40, and are therefore without limit.

FIG. 5 illustrates one embodiment of time shifter 50 (FIG. 1), which employs a delay locked loop (“DLL”) 51, conventional delay buffers 52-55, a multiplexor (“MUX”) 57, and a time shift register (“TSR”) 58. Delay locked loop 51 is a conventional delay locked loop for controlling an oscillating operation of delay buffers 52-55 in generating clock signals CS₁-CS₄ with a delay D (i.e., a time resolution) between clock signals CS₁-CS₄ in accordance with the following equation [1]:
D=TS_{—}CLK/n [1]

wherein n equals the number of delay buffers. Time shifter 50 as illustrated in FIG. 5 employs four (4) delay buffers 52-55. Delay D is therefore one-fourth the clock period of system clock signal TS_CLK.

Time shift register 58 is a conventional register for receiving, storing and communicating a time-shift register value TSRV, where 0≦TSRV<3. Multiplexor 57 is a conventional multiplexor for outputting clock signal TS_OUT as one of the clock signals CS₀-CS₃ based on the time-shift register value TSRV. Clock signal TS_OUT represents a time shift TS of system clock signal TS_CLK in accordance with the following equation [2]:
TS=TSRV*D [2]

where time shift TS equals 0, D, 2D or 3D in dependence upon time-shift register value TSR.

An exemplary operation of time shifter 50 will now be explained with reference to FIG. 6. In the exemplary operation, delay locked loop 51 controls delay buffers 52-55 in generating and communicating clock signals CS₁-CS₃ to multiplexor 57 as illustrated in FIG. 6. An input a₀ of multiplexor 57 receives a clock signal CS₀ (i.e., system clock signal TS_CLK) as illustrated in FIG. 6, while inputs a₁-a₃ of multiplexor 57 receive clocks signals CS₁-CS₃, respectively, as illustrated in FIG. 6. A control input CI of multiplexor 57 is electrically connected to time shift register 58 to receive time-shift register value TSRV, where time-shift register value TRSV equals 1. Multiplexor 57 therefore outputs clock signal TS_OUT as clock signal CS₁, based on the time-shift register value TSRV as illustrated in FIG. 6.

FIG. 7 illustrates a second embodiment of time shifter 50 (FIG. 1), which employs delay locked loop (“DLL”) 51, conventional delay buffers 52-54, a conventional inverting delay buffer 56, multiplexor (MUX”) 57, and time shift register (“TSR”) 58. An exemplary operation of time shifter 50 will now be explained with reference to FIG. 6. In the exemplary operation, delay locked loop 51 controls delay buffers 52-54 and 56 as a variable controlled oscillator, which generates clock signals CS₀-CS₃ with delay D in accordance with aforementioned equation [1]. Inputs a₀-a₃ of multiplexor 57 receive clocks signals CS₀-CS₃, respectively. Control input CI of multiplexor 57 receive time-shift register value TSRV, where TSRV equals 1. Multiplexor 57 outputs clock signal TS_OUT as clock signal CS₁, based on the time-shift register value TSRV as illustrated in FIG. 8. Clock signal TS_OUT thus represents a time shift TS of system clock signal TS_CLK in accordance with the aforementioned equation [2].

Referring to FIGS. 5 and 7, time shifter 50 is shown as outputting clock signal LR_CLK as system clock signal TS_CLK. In alternative embodiments, time shifter 50 can output clock signal LR_CLK as one of the clocks signals CS₁-CS₃. Additionally, more or less delay buffers may be implemented in an embodiment of time shifter 50 in accordance with equations [1] and [2] where clock signal LR_CLK can be outputted as system clock signal TS_CLK or as one of the delayed clock signals.

In practice, structural configurations of delayed lock loop 51, delay buffers 52-56, multiplexor 57, and time shift register 58 are dependent upon the commercial implementations of time shifter 50, and are therefore without limit.

FIG. 9 illustrates one embodiment of timer mixer 60 (FIG. 1), which employs a D flip-flop 61, a two-input AND gate 62 and a delay 63. An exemplary operation of mixer 60 will now be described herein in reference to FIG. 10. In the exemplary operation, a data input D of flip-flop 61 receives a logic high signal LHS, and a clock input of flip-flop 61 is electrically connected to timer 40 (FIG. 1) to receive timing signal LR_TC. In one embodiment of timer 40, flip-flop 61 is electrically connected to counter 42 (FIG. 3) to receive timing signal LR_TC.

A non-inverting output Q of flip-flop 61 is electrically connected to one input of AND gate 62. The other input of AND gate 62 is in electrically connected to time shifter 50 (FIG. 1) to receive clock signal TS_OUT. In one embodiment, the input of AND gate 62 is in electrically connected to multiplexor 57 (FIGS. 5 and 7) to receive clock signal TS_OUT.

Before time t₅, flip-flop 61 is cleared whereby the non-inverting output Q is at a logic low level. At time t₅, timing signal LR_TC pulses whereby the non-inverting output Q transitions to a logic high level as illustrated in FIG. 10. At time t₆, clock signal TS_OUT transitions to a logic high level whereby timing signal TC_OUT transitions to a logic high level as illustrated in FIG. 10. Delay 63 is controlled by a clock signal (not shown) having a frequency ≦D, whereby flip-flop 61 will be cleared before time t₇ as illustrated in FIG. 10. In summary, AND gate 62 performs a logical operation of clock signal TS_OUT and the non-inverting output Q of flip-flop 61 in pulsing timing signal TC_OUT subsequent to a pulsing of timing signal LR_TC with a time shift TS established by clock signal TS_OUT.

In practice, structural configurations of flip-flop 61, AND gate 62, and delay 63 are dependent upon the commercial implementations of mixer 60, and are therefore without limit.

From the preceding descriptions of FIGS. 1-10, those having ordinary skill in the art will appreciate the numerous advantages of timer 30 (FIG. 1). In particular, the advantage of timer 30 in generating high-resolution timing signal TC_OUT based on a low clock frequency of system clock signal TS_CLK (e.g., a high-resolution of 1 ns for a 100 MHz clock frequency of system clock signal TS_CLK based on the employment of ten (10) delay buffers).

A high-resolution pulse width modulator (“HRPWM”) 70 as illustrated in FIG. 11 generates a high-resolution pulse width modulated signal PWM_OUT with a high time resolution (e.g., 1 ns) based on a low clock frequency of system clock TS_CLK (e.g., a frequency between 50 MHz-100 MHz). To this end, high-resolution pulse width modulator 70 employs a low-resolution pulse width modulator (“LRPWM”) 80, a high-resolution time shifter (“HRTS”) 90, and a pulse width modulator mixer (“PWMM”) 100.

Pulse width modulator 80 is an electronic module structurally configured to generate a low-resolution pulse width modulated signal LR_PWM having a pulse width indicative of a counting of y number of clock cycles of low-resolution clock signal LR_CLK during a counting of x number of clock cycles of clock signal LR_CLK, where x≧1 and y≦x. Time shifter 90 is an electronic module structurally configured to generate a clock signal TS_OUT as an indication of a time shifting of system clock signal TS_CLK. Time shifter 90 is also structurally configured to generate clock signal LR_CLK as a function of system clock signal TS_CLK. Mixer 100 is an electronic module structurally configured to generate a high-resolution pulse width modulated signal PWM_OUT having a pulse width indicative of a mixture of the clock signal TS_OUT and the pulse width of the pulse width modulated signal LR_PWM.

An exemplary operation of pulse width modulator 70 will now be described in reference to FIG. 12. In the exemplary operation, time shifter 90 receives system clock signal TS_CLK as illustrated in FIG. 12, and in response thereto, generates clock signals TS_OUT and LR_CLK. Clock signal TS_OUT represents a high-resolution time shift TS of system clock signal TS_CLK. Clock signals TS_CLK and LR_CLK are identical in the illustrated examples of FIG. 12 to facilitate an understanding of the operation of pulse width modulator 70. However, in practice, clock signals TS_CLK and LR_CLK may be dissimilar (e.g., clock signal LR_CLK can also represent the time shift TS of system clock signal TS_CLK).

A time register value TRV equaling 2 and a pulse width register value PWRV equaling 1 are communicated to pulse width modulator 80 prior to a time t₀. Pulse width modulator 80 is conventionally triggered by a restart signal RESTART at time t₀ to initiate a count of two (2) clock cycles of clock signal LR_CLK at a time t₁, as illustrated in FIG. 12. Pulse width modulator 80 modulates a pulse width PW1 of pulse width modulated signal LR_PWM upon reaching a count of one clock cycle of clock signal LR_CLK at time t₃ as illustrated in FIG. 12.

Mixer 100 mixes clock signal TS_OUT and pulse width modulated signal LR_PWM to modulate a pulse width PW2 of pulse width modulated signal PWM_OUT at time t₄ as illustrated in FIG. 12. Pulse width PW2 represents an increase in the pulse width PW1 by time shift TS based on the clock signal TS_OUT, which represents the time shift TS of system clock signal TS_CLK. Time shift TS is a width differential between pulse width PW1 and pulse width PW2 that is a function of the time resolution of pulse width modulator 70.

In practice, structural configurations of pulse width modulator 80, time shifter 90 and mixer 100 are dependent upon the commercial implementations of pulse width modulator 70, and are therefore without limit.

FIG. 13 illustrates one embodiment of pulse width modulator 80 (FIG. 11), which employs a time register (“TR) 81, a counter (“CNTR”) 82, a pulse width register (“PWR”) 83, and a comparator (“CMP”) 84. Time register 81 is a conventional register for receiving, storing and communicating a time register value TRV as an indication of a total count threshold x for counter 82. Counter 82 is a conventional counter for generating a count signal LR_CNT as an indication of each count of a clock cycle of clock signal LR_CLK during a count x of the clock cycles of clock signal LR_CLK. Pulse width register 83 is a conventional register for receiving, storing and communicating a pulse width register value PWRV as an indication of a pulse width threshold y for comparator 84. Comparator 84 is a conventional comparator for generating pulse width modulated signal LR_PWM as an indication of a comparison of pulse width register value PWRV at a positive input and count signal LR_CNT at a negative input.

An exemplary operation of pulse width modulator 80 will now be explained with reference to FIG. 14. In the exemplary operation, time register 81 is electrically connected to a data input DI of counter 42 to electrically communicate a time register value TRV of 2 to counter 82 before a time t₀ as illustrated in FIG. 14. Counter 82 is conventionally triggered by the restart signal RESTART at a time t₀ to initiate a count of two (2) clock cycles of clock signal LR_CLK at time t₁.

Comparator 84 receives count signal LR_CNT and a pulse width register value PWRV of 1. Comparator 84 modulates the pulse width PW1 of pulse width modulate signal LR_PWM at time t₃ based on a comparison of count signal LR_CNT and a pulse width register value PWRV indicating count signal LR_CNT≧1.

In practice, structural configurations of time register 81, counter 82, pulse width register 83, and comparator 84 are dependent upon the commercial implementations of pulse width modulator 80, and are therefore without limit.

FIGS. 5 and 7 illustrate a couple of embodiments of time shifter 90 (FIG. 11).

FIG. 15 illustrates one embodiment of mixer 100 (FIG. 11), which employs a pair of two-input AND gates 101 and 102, and a RS flip-flop 103. One input of AND gate 101 is electrically connected to time shifter 90 (FIG. 11) to receive clock signal TS_OUT. In one embodiment, the input of AND gate 101 is electrically connected to multiplexor 57 (FIGS. 5 and 7) to receive clock signal TS_OUT.

The other input of AND gate 101 is electrically connected to a non-inverting output Q of RS flip-flop 103. A non-inverting input of AND gate 102 is electrically connected to an output of AND gate 101. An inverting input of AND gate 102 as well as a S input of flip-flop 103 are electrically connected to pulse width modulator 80 (FIG. 11) to receive pulse width modulated signal LR_PWM. In one embodiment of pulse width modulator 80, the inverting input of AND gate 102 and the S input of flip-flop 103 are electrically connected to comparator 84 (FIG. 13) to receive pulse width modulated signal LR_PWM.

A R input of RS flip-flop 103 is electrically connected to an output of AND gate 102.

An exemplary operation of mixer 100 will now be described herein in reference to FIG. 16. In the exemplary operation, AND gates 101 and 102 perform logical operations of clock signal TS_OUT, pulse width modulated signal LR_PWM, and the non-inverting output Q of RS flip-flop 103 whereby the R input of RS flip-flop 103 spikes at time t₄ to establish the modulation of pulse width PW2 at time t₄. Pulse width PW2 represents an increase in the pulse width PW1 by time shift TS based on the clock signal TS_OUT, which represents the time shift TS of system clock signal TS_CLK.

In practice, structural configurations of AND gates 101 and 102, and RS flip-flop 103 are dependent upon the commercial implementations of mixer 100, and are therefore without limit.

From the preceding descriptions of FIGS. 11-16, those having ordinary skill in the art will appreciate the numerous advantages of pulse width modulator 70 (FIG. 11). In particular, the advantage of pulse width modulator 70 in generating pulse width modulated signal PWM_OUT based on a low clock frequency of system clock signal TS_CLK (e.g., a high-resolution of 1 ns for a 100 MHz clock frequency of system clock signal TS_CLK based on the employment of ten (10) delay buffers).

A high-resolution timer (“HRT”) 110 as illustrated in FIG. 17 generates a high-resolution timing signal TC_OUT with a high time resolution (e.g., 1 ns) based on a low clock frequency of a system clock signal TS_CLK (e.g., a frequency between 50 MHz-100 MHz). To this end, high-resolution timer 110 employs a low-resolution timer (“LRT”) 120, a high-resolution time shifter in the form of a high-resolution delay compensator (“HRDC”) 130, and a timer mixer (“TM”) 140.

Timer 120 is an electronic module structurally configured to generate a low-resolution timing signal LR_TC having a pulse indicative of a counting of x number of clock cycles of a low-resolution clock signal LR_CLK, where x≧2. Time shifter 130 is an electronic module structurally configured to generate a high-resolution clock signal TS_OUT as an indication of a high-resolution time shifting of system clock signal TS_CLK as a function of restart signal RESTART. Mixer 140 is an electronic module structurally configured to generate timing signal TC_OUT having a pulse indicative of a mixture of clock signal TS_OUT and the pulse of timing signal LR_TC.

An exemplary operation of timer 110 will now be explained with reference to FIG. 18. In the exemplary operation, time shifter 130 receives system clock signal TS_CLK and restart signal RESTART as illustrated in FIG. 18 and in response thereto, generates clock signal DLY_OUT as a function of restart signal RESTART and a representation of a high-resolution time shift TS of system clock signal TS_CLK.

Before a time t₂, a time register value of 1 is communicated to timer 120. At time t₂, timer 120 is conventionally triggered by restart signal RESTART to initiate a count of one (1) clock cycle of system clock cycle TS_CLK at time t₃. At a time t₅, timer 120 generates a pulse of timing signal LR_TC upon counting one (1) clock cycle of system clock cycle TS_CLK as illustrated in FIG. 18. Mixer 140 mixes clock signal DLY_OUT and timing signal LR_TC to generate a pulse of timing signal TC_OUT at time t₆. The pulse of timing signal TC_OUT represents a high-resolution time shift TS of the pulse of timing signal LR_TC based on clock signal DLY_OUT, which represents a time shift TS of system clock signal TS_CLK as a function of the restart signal RESTART. Time shift TS is a time differential between the pulse of timing signal LR_TC and the pulse of TC_OUT that is a function of the time resolution of timer 110.

In practice, structural configurations of timer 120, time shifter 130 and mixer 140 are dependent upon the commercial implementations of timer 110, and are therefore without limit.

FIG. 3 illustrates one embodiment of timer 120 (FIG. 17), and FIG. 9 illustrates one embodiment of mixer 140 (FIG. 17).

FIG. 19 illustrates one embodiment of delay compensator 130 (FIG. 17), which employs a delay locked loop (“DLL”) 131, conventional delay buffers 132-135, a register (“REG”) 136, a decoder (“DEC”) 137 and a multiplexor (“MUX”) 138. Delay locked loop 131 is a conventional delay locked loop for controlling an oscillating operation of delay buffers 132-135 in generating clock signals CS₁-CS₄ with a delay D (i.e., a time resolution) between clock signals CS₁-CS₄ in accordance with the previously described equation [1]:
D=TS_{—}CLK/n [1]

wherein n equals the number of delay buffers. Delay compensator 130 as illustrated in FIG. 19 employs four (4) delay buffers 132-135. Delay D is therefore one-fourth the clock period of system clock signal TS_CLK.

Register 136 is a conventional register for receiving the clock signals CS₀-CS₃ and the restart signal RESTART, and in response to receiving the restart signal RESTART, for recording and communicating the recorded status of clock signals CS₀-CS₃ to decoder 137. Decoder 137 is a conventional decoder for receiving and communicating a decoded time-shifted value DTSV to multiplexor 138, where 0≦DTSV≦3 to represent a selection of one of the clock signals CS₀-CS₃ based on the current status of clock signals CS₀-CS₃. In one embodiment, decoder 137 selects the clock signal among clock signals CS₀-CS₃ that has the next rising clock edge.

Multiplexor 138 is a conventional multiplexor for outputting clock signal DLY_OUT as one of the clock signals CS₀-CS₃ based on the decoded time-shifted value DTSV. Clock signal DLY_OUT represents a time shift TS of system clock signal TS_CLK in accordance with the following equation [3]:
TS=DTSV*D [3]

where time shift TS equals 0, D, 2D or 3D in dependence upon decoded time-shifted value DTSV.

An exemplary operation of time shifter 130 will now be explained with reference to FIG. 20. In the exemplary operation, delay locked loop 131 controls delay buffers 132-135 in generating and communicating clock signals CS₁-CS₃ to multiplexor 138 as illustrated in FIG. 20. An input a₀ of multiplexor 138 receives a clock signal CS₀ (i.e., system clock signal TS_CLK) as illustrated in FIG. 20, while inputs a₁-a₃ of multiplexor 138 receive clocks signals CS₁-CS₃, respectively, as illustrated in FIG. 20. At time t₂, register 136 records and transmits the recorded status of clock signals CS₀-CS₃ to decoder 137, which transmits decoded time-shifted value DTSV to a control input CI of multiplexor 138 where decoded time-shifted value DTSV equals 1 due to the restart signal RESTART being synchronized with clock signal CS₁. Multiplexor 138 outputs clock signal DLY_OUT as clock signal CS₁, based on the decoded time-shifted value DTSV as illustrated in FIG. 20.

In practice, structural configurations of delayed lock loop 131, delay buffers 132-135, multiplexor 138, register 136 and decoder 137 are dependent upon the commercial implementations of timer 110, and are therefore without limit.

From the preceding descriptions of FIGS. 17-20, those having ordinary skill in the art will appreciate the numerous advantages of timer 110 (FIG. 17). In particular, the advantage of timer 110 in generating high-resolution timing signal TC_OUT based on a low clock frequency of system clock signal TS_CLK as synchronized with the restart signal RESTART (e.g., a high-resolution of 1 ns for a 100 MHz clock frequency of system clock signal TS_CLK based on the employment of ten (10) delay buffers).

A high-resolution pulse width modulator (“HRPWM”) 150 as illustrated in FIG. 21 generates a high-resolution pulse width modulated signal PWM_OUT with a high time resolution (e.g., 1 ns) based on a low clock frequency of system clock TS_CLK (e.g., a frequency between 50 MHz-100 MHz). To this end, high-resolution pulse width modulator 150 employs a low-resolution pulse width modulator (“LRPWM”) 160, a high-resolution time shifter in the form of a high-resolution delay compensator (“HRDC”) 170, and a pulse width modulator mixer (“PWMM”) 180.

Pulse width modulator 160 is an electronic module structurally configured to generate a low-resolution pulse width modulated signal LR_PWM having a pulse width indicative of a counting of y number of clock cycles of a system clock signal TS_CLK during a counting of x number of clock cycles of system clock signal TS_CLK, where x≧1 and y≦x. Delay compensator 170 is an electronic module structurally configured to generate a clock signal DLY_OUT as an indication of a time shifting of system clock signal TS_CLK as a function of restart signal RESTART. Mixer 180 is an electronic module structurally configured to generate a high-resolution pulse width modulated signal PWM_OUT having a pulse width as an indication of a mixture of the clock signal DLY_OUT and the pulse width of the pulse width modulated signal LR_PWM.

An exemplary operation of pulse width modulator 150 will now be explained in reference to FIG. 22. In the exemplary operation, delay compensator 170 receives system clock signal TS_CLK and restart signal RESTART as illustrated in FIG. 22, and in response thereto, generates clock signal DLY_OUT as an indication of a high-resolution time shift TS of system clock signal TS_CLK based on the restart signal RESTART.

A time register value TRV equaling 2 and a pulse width register value PWRV equaling 1 are communicated to pulse width modulator 160 prior to a time t₀. Pulse width modulator 160 is conventionally trigged by restart signal RESTART at time t₂ to initiate a count of two (2) clock cycles of system clock signal TS CLK at time t₃. Pulse width modulator 160 modulates a pulse width PW3 of pulse width modulated signal LR_PWM upon reaching a count of one (1) clock cycle of system clock signal TS_CLK at time t₅ as illustrated in FIG. 22.

Mixer 180 mixes clock signal DLY_OUT and pulse width modulated signal LR_PWM to modulate a pulse width PW4 of pulse width modulated signal PWM_OUT at time t₆ as illustrated in FIG. 22. Pulse width PW4 represents an increase in the pulse width PW3 by time shift TS based on the clock signal DLY_OUT, which represents the time shift TS of system clock signal TS_CLK as a function of restart signal RESTART. Time shift TS is a width differential between pulse width PW3 and pulse width PW4 that is a function of the time resolution of pulse width modulator 150.

In practice, structural configurations of pulse width modulator 160, delay compensator 170 and mixer 180 are dependent upon the commercial implementations of pulse width modulator 150, and are therefore without limit.

FIG. 23 illustrates one embodiment of pulse width modulator 160 (FIG. 21), which employs a time register (“TR) 161, a counter (“CNTR”) 162, a D flip-flop 163, a pulse width register (“PWR”) 164, a comparator (“CMP”) 165, and a two-input OR gate 166. Time register 161 is a conventional register for receiving, storing and communicating a time register value TRV as an indication of a total count threshold x for counter 162. Counter 162 is a conventional counter for generating a count signal LC_CNT as an indication of each count of a clock cycle of system clock signal TS_CLK during a count x of the clock cycles of system clock signal TS_CLK. Pulse width register 164 is a conventional register for receiving, storing and communicating a pulse width register value PWRV as an indication of a pulse width threshold y for comparator 165. Comparator 165 is a conventional comparator for generating a pulse width modulated signal LR_PWM as an indication of a comparison of pulse width register value PWRV at a positive input and count signal LC_CNT at a negative input.

An exemplary operation of pulse width modulator 160 will now be explained with reference to FIG. 24. In the exemplary operation, time register 161 is electrically connected to a data input DI of counter 42 to electrically communicate a time register value TRV of 2 to counter 162 before time t₂ as illustrated in FIG. 24. Counter 162 is conventionally triggered by the restart signal RESTART at a time t₂ to initiate a count of two (2) clock cycles of system clock signal TS_CLK at time t₃. Concurrently, D flip-flop 163 outputs a logic high signal LHS to one input of OR gate 166 at time t₂ as illustrated with the Q output of FIG. 24.

Comparator 165 receives count signal LC_CNT and a pulse width register value PWRV of 1. Comparator 165 modulates the pulse width of a pulse width modulate signal CMP_PWM at time t₅ based on a comparison of count signal LC_CNT and a pulse width register value PWRV indicating count signal LC_CNT≧1.

OR gate 166 performs a logical OR operation of the outputs of D flip-flop 163 and comparator 165 to yield pulse width modulated signal LR_PWM with a pulse width PW3 extending from time t₂ to time t₅.

In practice, structural configurations of time register 161, counter 162, D flip-flop 164, pulse width register 164, comparator 165 and OR gate 166 are dependent upon the commercial implementations of pulse width modulator 160, and are therefore without limit.

FIG. 19 illustrates one embodiment of delay compensator 170 (FIG. 22), and FIG. 15 illustrates one embodiment of mixer 180 (FIG. 22).

From the preceding descriptions of FIGS. 21-24, those having ordinary skill in the art will appreciate the numerous advantages of pulse width modulator 150 (FIG. 21). In particular, the advantage of pulse width modulator 150 in generating pulse width modulated signal PWM_OUT based on a low clock frequency of system clock signal TS_CLK as synchronized with the restart signal RESTART (e.g., a high-resolution of 1 ns for a 100 MHz clock frequency of system clock signal TS_CLK based on the employment of ten (10) delay buffers).

A high-resolution pulse width modulator (“HRPWM”) 190 as illustrated in FIG. 25 generates both a high-resolution pulse width modulated signal PWM_OUT and a high-resolution timing signal TC_OUT with a high time resolution (e.g., 1 ns and 2 ns, respectively) based on a low clock frequency of system clock TS_CLK (e.g., a frequency between 50 MHz-100 MHz). To this end, high-resolution pulse width modulator 190 employs a low-resolution pulse width modulator (“LRPWM”) 200, a high-resolution time shifter (“HRTS”) 230, a pulse width modulator mixer (“PWMM”) 220, and a timer mixer (“TM”) 210.

Pulse width modulator 200 is an electronic module structurally configured to generate a low-resolution pulse width modulated signal LROC_PWM and a low-resolution timing signal LROC_TC. Pulse width modulated signal LROC_PWM has a pulse width indicative of a counting of y number of clock cycles of a low-resolution clock signal LR_CLK during a counting of x number of clock cycles of clock signal LR_CLK, and timing signal LROC_TC has a pulse indicative of the a total counting of x number of clock cycles of clock signal LR_CLK, where x≧1 and y≦x.

Time shifter 230 is an electronic module structurally configured to generate a clock signal TS_OUT as an indication of a high-resolution time shifting of system clock signal TS_CLK as a function of restart signal RESTART. Time shifter 50 is also structurally configured to generate clock signal LR_CLK as a function of system clock signal TS_CLK.

Mixer 200 is an electronic module structurally configured to generate timing signal TC_OUT having a pulse indicative of a mixture of clock signal TS_OUT and the pulse of timing signal LROC_TC.

Mixer 220 is an electronic module structurally configured to generate high-resolution pulse width modulated signal PWM_OUT having a pulse width indicative of a mixture of the clock signal TS_OUT and the pulse width of the pulse width modulated signal LROC_PWM.

An exemplary operation of pulse width modulator 190 will now be explained in reference to FIG. 26. In the exemplary operation, time shifter 230 receives system clock signal TS_CLK and restart signal RESTART as illustrated in FIG. 22, and in response thereto, generates clock signal TS_OUT as an indication of a high-resolution time shift TS1 of system clock signal TS_CLK as a function of restart signal RESTART and a pulse width time shift value M1 from time t₂ to time t₈, and as an indication of a high-resolution time shift TS2 of system clock signal TS_CLK as a function of restart signal RESTART and a pulse width time shift value M2 beginning at time t₈. In essence, as will be further explained herein in connection with FIG. 29, clock signal TS_OUT is a first clock signal that is time shifted by TS1 to facilitate a high-resolution modulation of pulse modulated signal PWM_OUT, and a second clock signal that is time shifted by TS2 to facilitate a high-resolution pulsing of timing signal TC_OUT.

A time register value TRV equaling 2 and pulse width register value PWRV equaling 1 are communicated to pulse width modulator 200 prior to a time t₀. Pulse width modulator 200 is conventionally trigged by restart signal RESTART at time t₂ to initiate a count of two (2) clock cycles of clock signal LR_CLK beginning at time t₄. Pulse width modulator 200 modulates a pulse width PW5 of pulse width modulated signal LROC_PWM upon reaching a count of one (1) clock cycle of clock signal LR_CLK at time t₆ as illustrated in FIG. 26. Pulse width modulator 200 further pulses timing signal LROC_TC upon reaching a count of two (2) clock cycles of clock signal LR_CLK at a time t₉ as illustrated in FIG. 26.

Mixer 220 mixes clock signal TS_OUT and pulse width modulated signal LROC_PWM to modulate a pulse width PW5 of pulse width modulated signal PWM_OUT at time t₈ as illustrated in FIG. 26. Pulse width PW6 represents an increase in the pulse width PW5 by time shift TS1 based on the clock signal TS_OUT, which represents the time shift TS1 of system clock signal TS_CLK as a function of restart signal RESTART and pulse width time shift value M1. Specifically, time shift TS1 consists of an asynchronous time differential AD between restart signal RS and a preceding rising edge of system clock TS_CLK as illustrated in FIG. 26. Time shift TS1 further consists of a delay D1, which is a function of pulse width time shift value M1 as will be further explained herein in connection with a description of one embodiment of time shifter 230 as illustrated in FIG. 29. Time shift TS1 is a width differential between pulse width PW5 and pulse width PW6 that is a function of the pulse width time resolution of pulse width modulator 190.

Mixer 210 mixes clock signal TS_OUT and timing signal LROC_TC to generate a pulse of timing signal TC_OUT at time t₁₂. The pulse of timing signal TC_OUT represents a time shift TS2 of the pulse of timing signal LROC_TC based on clock signal TS_OUT, which represents a time shift TS2 of system clock signal TS_CLK as a function of restart signal RESTART and period time shift value M2. Specifically, time shift TS2 consists of asynchronous time differential AD between restart signal RS and a preceding rising edge of system clock TS_CLK as illustrated in FIG. 26. Time shift TS2 further consists of a delay D2, which is a function of period time shift value M2 as will be further explained herein in connection with a description of one embodiment of time shifter 230 as illustrated in FIG. 29. Time shift TS2 is a time differential between the pulse of timing signal LROC_TC and the pulse of timing signal TC_OUT that is a function of the period time resolution of pulse width modulator 190.

Also, as will be further explained in connection with a description of one embodiment of time shifter 230 as illustrated in FIG. 29, time shifter 29 provides an over-carrier signal OC to modulator 200 whenever time shift TS1 exceeds a clock period of system clock signal TS_CLK and whenever time shift TS2 exceeds the clock period of system clock signal TS_CLK. In turn, modulator 200 extends a modulation of pulse width PW5 for one clock cycle of clock signal LR_CLK (e.g., ending pulse width PW5 at time t₉ instead of time t₆ as shown in FIG. 26) whenever over-carrier signal OC represents time shift TS1 exceeding the clock period of system clock signal TS_CLK whereby the modulation of pulse width PW6 is also extend over one clock cycle of clock signal LR_CLK. Additionally, modulator 200 delays a pulsing of timing signal LROC_TC for one clock cycle of clock signal LR_CLK (e.g., LROC_TC pulses at time t₁₃ instead of time t₉ as shown in FIG. 26) whenever over-carrier signal OC represents time shift TS2 exceeding the clock period of system clock signal TS_CLK whereby the pulsing of timing signal TC_OUT is also delayed for one clock cycle of clock signal LR_CLK.

In practice, structural configurations of pulse width modulator 200, time shifter 230, mixer 220 and mixer 210 are dependent upon the commercial implementations of pulse width modulator 190, and are therefore without limit.

FIG. 27 illustrates one embodiment of pulse width modulator 200 (FIG. 25), which employs a low-resolution pulse width modulator (“LRPWM”) 201, a pair of 1-bit counters (“1BC”) 202 and 203, and a RS flip-flop 204.

Modulator 201 is an electronic module structurally configured to generate a low-resolution pulse width modulated signal LR_PWM and a low-resolution timing signal LR_TC. Pulse width modulated signal LR_PWM has a pulse width indicative of a counting of y number of clock cycles of a low-resolution clock signal LR_CLK during a total counting of x number of clock cycles of clock signal LR_CLK, and timing signal LR_TC has a pulse indicative of the counting of x number of clock cycles of clock signal LR_CLK, where x≧1 and y≦x. In one embodiment, modulator 201 is the modulator 160 (FIG. 23) as described herein with the added function of counter 162 conventionally outputting timing signal LR_TC.

Modulator 201 communicates pulse width modulated signal LR_PWM to counter 202 and a S input of flip-flop 204, and communicates timing signal LR_TC to counter 203. Time shifter 230 (FIG. 25) communicates over-carrier signal OC to counters 202 and 203. An output of counter 202 is electrically connected to a R input of flip-flop 204.

An exemplary operation of pulse width modulator 200 will now be explained with reference to FIG. 28. In the exemplary operation, modulator 201 conventionally generates pulse width modulation signal LR_PWM, and counter 202 and flip-flop 204 generate pulse width modulation signal LROC_PWM as a function of pulse width modulation signal LR_PWM and over-carrier signal OC. As illustrated in FIG. 28, over-carrier signal OC equals 0 and the pulse width PW5 of pulse width modulation signal LROC_PWM extends from time t₂ to time t₆. Conversely, if over-carrier signal OC equaled 1, then the pulse width PW5 of pulse width modulation signal LROC_PWM would extend from time t₂ to time t₉.

Modulator 201 also conventionally generates timing signal LR_TC, and counter 203 generate pulses timing signal LROC_TC as a function of timing signal LR_TC and over-carrier signal OC. As illustrated in FIG. 28, over-carrier signal OC equals 0 and the pulse of pulse width timing signal LROC_TC occurs at time t₉. Conversely, if over-carrier signal OC equaled 1, then the pulse of timing signal LROC_TC would occur at time t₁₃.

In practice, structural configurations of modulator 201, counters 202 and 203, and flip-flop 204 are dependent upon the commercial implementations of pulse width modulator 200, and are therefore without limit.

FIG. 29 illustrates one embodiment of time shifter 230 (FIG. 25), which employs a delay locked loop (“DLL”) 231, conventional delay buffers 232-235, register (“REG”) 236, a decoder (“DEC”) 237, a multiplexor (“MUX”) 238, a multiplexor (“MUX”) 239, a pulse width time shift register (“PWTSR”) 240, and a period time shift register (“PTSR”) 241. Delay locked loop 231 is a conventional delay locked loop for controlling an oscillating operation of delay buffers 232-235 in generating clock signals CS₁-CS₄ with a delay D (i.e., time resolution) between clock signals CS₁-CS₄ in accordance with the previously described equation [1]:
D=TS_{—}CLK/n [1]

wherein n equals the number of delay buffers. Time shifter 230 as illustrated in FIG. 19 employs four (4) delay buffers 232-235. Delay D is therefore one-fourth the clock period of system clock signal TS_CLK.

Register 236 is a conventional register for receiving the clock signals CS₀-CS₃ and the restart signal RESTART, and in response to receiving the restart signal RESTART, for recording and communicating the recorded status of clock signals CS₀-CS₃ to decoder 237. Decoder 237 is a conventional decoder for receiving and communicating a decoded time-shifted value DTSV to multiplexor 238, where 0≦DTSV≦3 represents a selection of one of the clock signals CS₀-CS₃ based on the current status of clock signals CS₀-CS₃.

In generating decoded time-shifted value DTSV, decoder 237 receives a communication of either pulse width time shift value M1 or period time shift value M2 from multiplexor 239, which is conventional multiplexor for outputting pulse width time shift value M1 or period time shift value M2 as a function of pulse width modulated signal PWM_OUT. Register 240 is a conventional register for storing and communicating pulse width time shift value M1 to multiplexor 239. Register 241 is a conventional register for storing and communicating period time shift value M2 to multiplexor 239. Decoder 237 outputs over-carrier signal OC at a logic high level whenever time shift TS1 or TS2 (FIG. 25) exceeds a clock period of system clock TS_CLK).

Multiplexor 238 is a conventional multiplexor for outputting clock signal TS_OUT as one of the clock signals CS₀-CS₃ based on the decoded time-shifted value DTSV. Clock signal TS_OUT represents a time shift TS of system clock signal TS_CLK in accordance with the following equation [3]:
TS=DTSV*D [3]

where time shift TS equals 0, D, 2D or 3D in dependence upon decoded time-shifted value DTSV.

An exemplary operation of time shifter 230 will now be explained with reference to FIG. 30. In the exemplary operation, delay locked loop 231 controls delay buffers 232-235 in generating and communicating clock signals CS₁-CS₃ to multiplexor 238 as illustrated in FIG. 20. An input a₀ of multiplexor 238 receives a clock signal CS₀ (i.e., system clock signal TS_CLK) as illustrated in FIG. 20, while inputs a₁-a₃ of multiplexor 238 receive clocks signals CS₁-CS₃, respectively, as illustrated in FIG. 20. At time t₂, register 236 records and transmits the recorded status of clock signals CS₀-CS₃ to decoder 237 and multiplexor 239 communicates pulse width time shift value M1 equaling 1 to decoder 237 in view of pulse width modulated signal being a logic high level. Decoder 237 transmits decoded time-shifted value DTSV to a control input CI of multiplexor 238 where decoded time-shifted value DTSV equals 2 due to the restart signal RESTART being synchronized with clock signal CS₂. Multiplexor 238 outputs clock signal TC_OUT as clock signal CS₂ from time t₂ to time t₈ as illustrated in FIG. 30. Time shift TS1 (FIG. 25) therefore equal 2D.

At time t₈, multiplexor 239 communicates pulse width time shift value M2 equaling 2 to decoder 237 in view of pulse width modulated signal being a logic low level. Decoder 237 transmits decoded time-shifted value DTSV to a control input CI of multiplexor 238 where decoded time-shifted value DTSV equals 3. Multiplexor 238 outputs clock signal TC_OUT as clock signal CS₃ from time t₈ on as illustrated in FIG. 30. Time shift TS2 (FIG. 25) therefore equal 3D.

In practice, structural configurations of delayed lock loop 231, delay buffers 232-235, register 236, decoder 237, multiplexers 238 and 239, and registers 240 and 241 are dependent upon the commercial implementations of pulse width modulator 230, and are therefore without limit.

FIG. 15 illustrates one embodiment of mixer 220 (FIG. 25), and FIG. 9 illustrates one embodiment of mixer 210 (FIG. 25).

From the preceding descriptions of FIGS. 25-30, those having ordinary skill in the art will appreciate the numerous advantages of pulse width modulator 190 (FIG. 25). In particular, the advantage of pulse width modulator 190 in generating pulse width modulated signal PWM_OUT and timing signal TC_OUT based on a low clock frequency of system clock signal TS_CLK as synchronized with the restart signal RESTART (e.g., a high-resolution of 1 ns for a 100 MHz clock frequency of system clock signal TS_CLK based on the employment of ten (10) delay buffers).

While the embodiments of the invention disclosed herein are presently considered to be preferred, various changes and modifications can be made without departing from the spirit and scope of the invention. The scope of the invention is indicated in the appended claims, and all changes that come within the meaning and range of equivalents are intended to be embraced therein.

1. A method of operating a timer (30, 110), said method comprising:
generating a first clock signal (TS_OUT, DLY_OUT) indicative of a first time shifting of a second clock signal (TS_CLK);
generating a first timing signal (LR_TC) having a first pulse; and
generating a second timing signal (TC_OUT) having a second pulse indicative of a mixture of the first clock signal (TS_OUT, DLY_OUT) and the first pulse of the first timing signal (LR_TC),
wherein a time differential between the first pulse of the first timing signal (LR_TC) and the second pulse of the second timing signal (TC_OUT) is a function of a time resolution of the timer (30, 110).

2. The method of claim 1,
wherein the first pulse of the first timing signal (LR_TC) is indicative of a total counting of a specified number of clock cycles of a third clock signal (LR_CLK); and
wherein the third clock signal (LR_KCLK) is a function of the second clock signal (TS_CLK).

3. The method of claim 1, wherein the first time shifting of the second clock signal (TS_CLK) is a function of a restart signal (RESTART) for triggering the timer (110).

4. The method of claim 1, wherein the mixture the first clock signal (TS_OUT, DLY_OUT) and the first pulse of the first timing signal (LR_TC) is a second time shifting of the first pulse of the first timing signal (LR_TC) as a function of the first clock signal (TS_OUT, DLY_OUT).

5. A timer (30, 110), comprising:
a time shifter module (50, 130) operable to generate a first clock signal (TS_OUT, DLY_OUT) indicative of a first time shifting of a second clock signal (TS_CLK);
a timer module (40, 120) operable to generate a first timing signal (LR_TC) having a first pulse; and
a timer mixer module (60, 140) in electrical communication with said time shifter module (50, 130) to receive the first clock signal (TS_OUT, DLY_OUT) and in electrical communication with said timer module (40, 120) to receive the first timing signal (LR_TC), said timer mixed module (60, 140) operable to generate a second timing signal (TC_OUT) having a second pulse indicative of a mixture of the first clock signal (TS_OUT, DLY_OUT) and the first pulse of the first timing signal (LR_TC),
wherein a time differential between the first pulse of the first timing signal (LR_TC) and the second pulse of the second timing signal (TC_OUT) is a function of a time resolution of the timer (30, 110).

6. The timer (30, 110) of claim 5,
wherein the first pulse of the first timing signal (LR_TC) is indicative of a total counting of a specified number of clock cycles of a third clock signal (LR_CLK); and
wherein the third clock signal (LR_CLK) is a function of the second clock signal (TS_CLK).

7. The timer (30, 110) of claim 6, wherein said timer module (40, 120) includes:
a time register module (41) operable to store a time register value (TRV) indicative of the specified number of clock cycles; and
a counter module (42) in electrical communication with said time register module (41) to receive the time register value (TRV), said counter module (42) operable to count up to the specified number clock cycles of the third clock signal (LR_CLK) as indicated by the time register value, said counter module (42) further operable to generate the first pulse of the first timing signal (LR_TC) in response to the total counting of the specified number of clock cycles of the third clock signal (LR_CLK).

8. The timer (30) of claim 5, wherein said time shifter module (50) includes:
at least one delay buffer (52-56);
a delay locked loop module (51) operable to control an operation of said at least one delay buffer (52-56) in generating at least one clock signal (CS₁-CS₃) indicative of one or more delays of the second clock signal (TS_CLK);
a time shift register module (58) operable to generate a time-shifted register value (TSRV); and
a multiplexor module (57) in electrical communication with said at least one delay buffer (52-56) to receive the at least one clock signals (CS₁-CS₃) and in electrical communication with said time shift register module (58) to receive the time-shifted register value (TSRV), said multiplexor module (57) operable to generate the first clock signal (TS_OUT) as one of the at least one clock signals (CS₁-CS₃) based on the time-shifted register value (TSRV).

9. The timer (110) of claim 5, wherein the first time shifting of the second clock signal (TS_CLK) is a function of a restart signal (RESTART) for triggering the timer (110).

10. The timer (110) of claim 9, wherein said time shifter module (130) includes:
at least one delay buffer (132-135);
a delay locked loop module (131) operable to control an operation of said at least one delay buffer (132-135) in generating at least one clock signal (CS₁-CS₃) indicative of one or more delays of the second clock signal (TS_CLK);
a register module (138) operable to record a status of the at least one clocks signals (CS₁-CS₃) as a function of the restart signal (RESTART);
a decoder module (139) operable to generate a decoded time-shifted value (DTSV) as an indication of a decoding of the recorded status of the at least one clock signals (CS₁-CS₃);
a multiplexor module (137) in electrical communication with said at least one delay buffer (132-135) to receive the at least one clock signals (CS₁-CS₃) and in electrical communication with said decoder module (139) to receive the decoded time-shifted value (DTSV), said multiplexor module (137) operable to generate the first clock signal (DLY_OUT) as one of the at least one clock signals (CS₁-CS₃) based on the decoded time-shifted value (DTSV).

11. The timer (30, 110) of claim 5, wherein said time shifter (50, 130) includes means (51-58, 131-139) for establishing the first time shifting of the second clock signal (TS_CLK) as a function of the time resolution of said timer (30, 110).

12. The timer (30, 110) of claim 5, wherein said timing mixer module (60, 140) includes means (61-63) for generating the second pulse of the second timing signal (TC_OUT) as a function of a second time shifting of the first pulse of the first timing signal (LR_TC) based on the first clock signal (TS_OUT, DLY_OUT).

13. A method of operating a pulse width modulator (70, 150, 190), said method comprising:
generating a first clock signal (TS_OUT, DLY_OUT) indicative of a first time shifting of a second clock signal (TS_CLK);
generating a first pulse width modulated signal (LR_PWM, LROC_PWM) having a first pulse width (PW1, PW3, PW5); and
generating a second pulse width modulated signal (PWM_OUT) having a second pulse width (PW2, PW4, PW6) indicative of a mixture of the first clock signal (TS_OUT, DLY_OUT) and the first pulse width (PW1, PW3, PW5) of the first pulse width modulated signal (LR_PWM, LROC_QPWM),
wherein a width differential between the first pulse width (PW1, PW3, PW5) of the first pulse width modulated signal (LR_PWM, LROC_PWM) and the second pulse width (PW2, PW4, PW6) of the second pulse width modulated signal (PWM_OUT) is a function of a first time resolution of the pulse width modulator (70, 150, 190).

14. The method of claim 13,
wherein the first pulse width (PW1, PW3, PW5) is indicative of a first counting of a first specified number of clock cycles of a third clock signal (LR_CLK) during a second counting of a second specified number of clock cycles of the third clock signal (LR_CLK); and
wherein the third clock signal (LR_CLK) is a function of the second clock signal (TS_CLK).

15. The method of claim 13, wherein the first time shifting of the second clock signal (TS_CLK) is a function of a restart signal (RESTART) for triggering the pulse width modulator (70, 150, 190).

16. The method of claim 13, wherein the mixture the first clock signal (TS_OUT, DLY_OUT) and the first pulse width (PW1, PW3, PW) of the first pulse width modulated signal (LR_PWM, LROC_PWM) is a second time shifting of the first pulse width (PW1, PW3, PW) of the first pulse width modulated signal (LR_PWM, LROC_PWM) as a function of the first clock signal (TS_OUT, DLY_OUT).

17. The method of claim 13, further comprising:
generating a third clock signal (TS_OUT) indicative of a second time shifting of the second clock signal (TS_CLK);
generating a first timing signal (LROC_TC) having a first pulse; and
generating a second timing signal (TC_OUT) having a second pulse indicative of a mixture of the third clock signal (TS_OUT) and the first pulse of the first timing signal (LR_TC),
wherein a time differential between the first pulse of the first timing signal (LROC_TC) and the second pulse of the second timing signal (TC_OUT) is a function of a second time resolution of the pulse width modulator (70, 150, 190).

18. The method of claim 17,
wherein the first pulse of the first timing signal (LROC_TC) is indicative of a total counting of a specified number of clock cycles of a fourth clock signal (LR_CLK); and
wherein the fourth clock signal (LR_CLK) is a function of the second clock signal (TS_CLK).

19. The method of claim 17, wherein the second time shifting of the second clock signal (TS_CLK) is a function of a restart signal (RESTART) for triggering the pulse width modulator (70, 150, 190).

20. The method of claim 17, wherein the mixture of the third clock signal (TS_OUT) and the first pulse of the first timing signal (LROC_TC) is a second time shifting of the first pulse of the first timing signal (LROC_TC) as a function of the first clock signal (TS_OUT).

21. A pulse width modulator (70, 150, 190), comprising:
a time shifter module (90, 170, 230) operable to generate a first clock signal (TS_OUT, DLY_OUT) indicative of a first time shifting of a second clock signal (TS_CLK);
a pulse width modulator module (80, 160, 200) operable to generate a first pulse width modulated signal (LR_PWM, LROC_PWM) having a first pulse width (PW1, PW3, PW5); and
a pulse width modulator mixer module (100, 180, 220) in electrical communication with said time shifter module (90, 170, 230) to receive the first clock signal (TS_OUT, DLY_T) and in electrical communication with said pulse width modulator module (80, 160, 200) to receive the first pulse width modulated signal (LR_PWM, LROC_PWM), said pulse width modulator mixer module (100, 180, 220) operable to generate a second pulse width modulated signal (PWM_OUT) having a second pulse width (PW2, PW4, PW6) indicative of a mixture of the first clock signal (TS_OUT, DLY_OUT) and the first pulse width (PW1, PW3, PW5) of the first pulse width modulated signal (LR_PWM, LROC_PWM),
wherein a width differential between the first pulse width (PW1, PW3, PW5) of the first pulse width modulated signal (LR_PWM, LROC_PWM) and the second pulse width (PW2, PW4, PW6) of the second pulse width modulated signal (PWM_OUT) is a function of a first time resolution of the pulse width modulator (70, 150, 190).

22. The pulse width modulator (70, 150, 190) of 21,
wherein the first pulse width (PW1, PW3, PW5) is indicative of a first counting of a first specified number of clock cycles of a third clock signal (LR_CLK) during a second counting of a second specified number of clock cycles of the third clock signal (LR_CLK); and
wherein the third clock signal (LR_CLK) is a function of the second clock signal (TS_CLK).

23. The pulse width modulator (70) of claim 22, wherein said pulse width modulator module (80) includes:
a time register module (81) operable to store a time register value (TRV) indicative of the first specified number of clock cycles of the third clock signal (LR_CLK);
a counter module (82) in electrical communication with said register module (81) to receive the time register value (TRV), said counter module (82) operable to generate a count signal (LR_CNT) indicative of the second counting of the specified number of clock cycles of the third clock signal (LR_CLK) based on the time register value (TRV);
a pulse width register module (83) operable to store a pulse width register value (PWRV) indicative of the first specified number of clock cycles of the third clock signal (LR_CLK); and
a comparator module (84) in electric communication with said counter module (82) to receive the count signal (LR_CNT) and in electric communication with said second register module (83) to receive the pulse width register value (PWRV), said comparator module (84) operable to generate the first pulse width modulated signal (LR_PWM) including the first pulse width (PW1) based on a comparison of the pulse width register value (PWRV) and the second counting of the second specified number of clock cycles of the third clock signal (LR_CLK).

24. The pulse width modulator (150) of claim 22, wherein said pulse width modulator module (160) includes:
a time register module (161) operable to generate a time register value (TRV) indicative of the first specified number of clock cycles of the third clock signal (TS_CLK);
a counter module (162) in electrical communication with said register module (161) to receive the time register value (TRV), said counter module (162) operable to generate a count signal (LC_CNT) indicative of the second counting of the specified number of clock cycles of the third clock signal (LR_CLK) based on the time register value (TRV);
a pulse width register module (164) operable to generate a pulse width register value (PWRV) indicative of the first specified number of clock cycles of the third clock signal (TS_CLK);
a comparator module (165) in electric communication with said counter module (82) to receive the count signal (LC_CNT) and in electric communication with said second register module (83) to receive the pulse width register value (PWRV), said comparator module (84) operable to generate a third pulse width modulated signal (CMP_PWM) based on a comparison of the pulse width register value (PWRV) and the second counting of the second specified number of clock cycles of the third clock signal (TS_CLK).
a flip-flop module (163) operable to generate a logic signal (Q) in response to a restart signal (RESTART) for triggering the pulse width modulator (150); and
a logic module (166) in electrical communication with said comparator module (165) to receive the third pulse width modulated signal (CMP_PWM) and in electrical communication with said flip-flop module (163) to receive the logic signal (Q), said logic module (166) operable to modulate a pulse width (PW3) of the first pulse width modulated signal (LR_PWM) based on the logic signal (Q) and the third pulse width modulated signal (CMP_PWM).

25. The pulse width modulator (70, 150, 190) of claim 21, wherein said time shifter module (90, 170, 230) includes:
at least one delay buffer (52-56);
a delay locked loop module (51) operable to control an operation of said at least one delay buffer (52-56) in generating at least one clock signal (CS₁-CS₃) indicative of one or more delays of the second clock signal (TS_CLK);
a time shift register module (58) operable to generate a time-shifted register value (TSRV); and
a multiplexor module (57) in electrical communication with said at least one delay buffer (52-56) to receive at least one clock signals (CS₁-CS₃) and in electrical communication with said time shift register module (58) to receive the time-shifted register value (TSRV), said multiplexor module (57) operable to generate the first clock signal (TS_OUT) as one of the at least one clock signals (CS₁-CS₃) based on the time-shifted register value (TSRV).

26. The pulse width modulator (70, 150, 190) of claim 21, wherein the first time shifting of the second clock signal (TS_CLK) is a function of a restart signal (RESTART) for triggering the pulse width modulator (70, 150, 190).

27. The pulse width modulator (70, 150, 190) of claim 26, wherein said time shifter module (50, 130) includes:
at least one delay buffer (132-135);
a delay locked loop module (131) operable to control an operation of said at least one delay buffer (132-135) in generating at least one clock signal (CS₁-CS₃) indicative of one or more delays of the second clock signal (TS_CLK);
a register module (136) operable to record a status of the at least one clock signals (CS₁-CS₃) as a function of a restart signal (RESTART);
a decoder module (137) in electrical communication with said register module (136) to receive the recorded status of the at least one clock signal (CS₁-CS₃), said decoder module (137) operable to generate a decoded time-shifted value (DTSV) indicative of a decoding of the recorded status of the clock signals (CS₁-CS₃);
a multiplexor module (138) in electrical communication with said at least one delay buffer (132-135) to receive at least one clock signals (CS₁-CS₃) and in electrical communication with said decoder module (137) to receive the decoded time-shifted value (DTSV), said multiplexor module (138) operable to generate the first clock signal (TS_OUT) as one of the at least one clock signals (CS₁-CS₃) based on the decoded time-shifted value (DTSV).

28. The pulse width modulator (70, 150, 190) of claim 21, wherein said time shifter (50, 130) includes means (51-58) for establishing the first time shifting of the second clock signal (TS_CLK) as a function of a time resolution of said pulse width modulator (70, 150, 190).

29. The pulse width modulator (70, 150, 190) of claim 21, wherein said pulse width modulated mixer module (100, 180, 220) includes means (61-63) for modulator the pulse width (PW2, PW4, PW6) of the second pulse width modulate signal (PWM_OUT) as a function of a modulation of the pulse width (PW1, PW3, PW5) of the first pulse width modulate signal (LR_PWM, LROC_PWM) based on the first clock signal (TS_OUT).

30. The pulse width modulator (70, 150, 190) of claim 21, further comprising:
a timer module (210);
wherein said time shifter module (230) is further operable to generate a third clock signal (TS_OUT) indicative of a second time shifting of the second clock signal (TS_CLK);
wherein said pulse width modulator module (200) is further operable to generate a first timing signal (LROC_TC) having a first pulse;
wherein said timer mixer module (210) is in electrical communication with said time shifter module (230) to receive the third clock signal (TS_OUT) and in electrical communication with said pulse width modulator module (200) to receive the first timing signal (LROC_TC);
wherein said timer mixer module (21) is operable to generate a second timing signal (TC_OUT) having a second pulse indicative of a mixture of the third clock signal (TS_OUT) and the first pulse of the first timing signal (LR_TC); and
wherein a time differential between the first pulse of the first timing signal (LROC_TC) and the second pulse of the second timing signal (TC_OUT) is a function of a second time resolution of the pulse width modulator (190).

31. The pulse width modulator (190) of claim 30,
wherein said time shifter module (230) includes means for generating an over-carrier signal (OC) indicative of at least one of the first time shifting and the second time shifting of the second clock (TS_CLK) exceeding a clock period of the second clock signal (TS_CLK); and
wherein said pulse width modulator module (200) includes means (201-204) for generating the first pulse width (PW5) of the first pulse width modulated signal (LROC_PWM) and the first pulse of the first timing signal (LROC_TC) as a function of the over-carrier signal.

32. The pulse width modulator (190) of claim 30,
wherein said time shifter module (230) includes means for executing the first time shifting of the second clock signal (TS_CLK) as a function of a pulse width time shift value (M1) associated with the first time resolution of the pulse width modulator (190); and
wherein said time shifter module (230) includes means for executing the second time shifting of the second clock signal (TS_CLK) as a function a period time shift value (M2) associated with the second time resolution of the pulse width modulator (190).
